(19) United States
(12) Patent Application Publication
(10) Pub. No.: US 2022/0131763 A1
(43) Pub. Date: Apr. 28, 2022

(54) SYSTEM CONFIGURATION DERIVATION DEVICE AND SYSTEM CONFIGURATION DERIVATION METHOD

(71) Applicant: NEC Corporation, Minato-ku, Tokyo (JP)

(72) Inventor: Takuya KUWAHARA, Tokyo (JP)

(21) Appl. No.: 17/434,534

(22) PCT Filed: Dec. 12, 2019
(86) PCT No.: PCT/JP2019/048619

§ 371 Date: Aug. 27, 2021

(30) Foreign Application Priority Data
Mar. 1, 2019 (JP) 2019-037180

(51) Int. Cl. H04L 41/14

(52) U.S. Cl. CPC H04L 41/145

(57) ABSTRACT

A system configuration derivation device 20 includes an actualization unit 21 which actualizes abstract configuration information including an unconfirmed portion and indicating a system configuration, the actualization being performed on the basis of an actualization rule in which a method for actualizing the abstract configuration information by confirming the unconfirmed portion of the abstract configuration information is defined; and actualization information which indicates the results of actualizing the unconfirmed portion by using an external design device that can actualize the abstract configuration information only for a predetermined problem.

### TECHNICAL FIELD

The present invention relates to a system configuration derivation device and a system configuration derivation method, and in particular to a system configuration derivation device and a system configuration derivation method for automatically generating a desired ICT (Information and Communication Technology) system on the basis of user requirements.

### BACKGROUND ART

The work of constructing ICT systems for the purpose of service operation, etc., mainly includes the work of designing the system configuration and the work of designing the deployment procedures.

In particular, the work of designing the system configuration is required to construct the system components and the connection relationships among the components (hereinafter collectively referred to as the system configuration) that are required to satisfy the requirements of the desired system (hereinafter referred to as the system requirements), without insufficiency.

In addition, the work of designing the system configuration requires the correct setting of all the configuration items that are required for the entire system to operate properly. Therefore, the man-hours required to design a system configuration are generally large.

The technology that automates the above work of designing, i.e., deriving an actualized system configuration from system requirements, is automatic design technology. Many existing automatic design technologies perform automatic design by restricting the problem to a specific domain of the ICT system and solving a given type of optimization problem, etc. with the restriction. Here, a domain means a predetermined problem, such as a communication network route or a computational resource arrangement, and the specification of input and output in a predetermined problem (the same applies hereinafter).

For example, Patent Literature (PTL) 1 describes a technique for automatically designing a communication network. The communication network design scheme described in PTL 1 can design a communication network that minimizes the delay time on the basis of the required communication volume between outgoing nodes, incoming nodes, and nodes, the budget required for equipment installation, and the total budget available.

For example, PTL 2 describes a method for determining the physical machine to which a virtual machine is to be deployed on the basis of the software running on the virtual machine and the operation policy of the software.

The methods described in PTL 1 or PTL 2 can automatically derive the design corresponding to each domain. However, if the system requirements do not correspond to the domains, the above existing techniques cannot derive the design corresponding to the domain.

The system requirements do not correspond to the domain, for example, when it is required to consider the communication network design issues and virtual machine deployment issues at the same time, or when it is required to further consider the requirements of another domain, such as security requirements.

In addition, Non Patent Literature (NPL) 1 describes a technique for automatically deriving system configurations on the basis of requirements described using a generic model. The technology described in NPL 1 can perform automatic design with generic and multifaceted requirements as input by preparing the required model, without specializing in a limited purpose as in the methods described in PTLs 1-2, etc.

### CITATION LIST

### Patent Literature

PTL 1: Japanese Patent Application Laid-Open No. 1994-90235
PTL 2: International Publication No. WO 2013/072978

### Non Patent Literature

NPL 1: Search-based network design generation scheme for closed-loop automation of network operations, IEICE Technical Report, vol. 118, no. 118, ICM2018-11, pp. 1-6, July 2018.

### SUMMARY OF INVENTION

### Technical Problem

As mentioned above, the technology described in NPL 1 can maintain models of the required system components and also extend the models according to further requirements. In addition, the technology described in NPL 1 represents the requirements for which all models are combined in a general attributed graph, and performs automatic design by applying rules for rewriting parts of the predefined attributed graph to the represented graph.

In other words, a device to which the technology described in NPL 1 is applied can consider a wide variety of requirements for design together. Compared to domain-specific automatic design techniques, it is considered that a device applied the technology described in NPL 1 can reduce the more overall man-hours required for the work of designing the system configuration.

However, domain-specific algorithms do not have to consider elements that are unrelated to the target domain. Also, domain-specific algorithms can use the common properties of elements related to the target domain. Therefore, compared to algorithms that deal with generic inputs, domain-specific algorithms can derive the optimal solution for the target domain faster.

In other words, generic design methods such as those described in NPL 1 may be slower in execution speed or inferior in quality of the generated system configuration compared to optimization or automation techniques that are more specialized in the target domain. In the following, existing optimal or automatic design devices are referred to as external design devices.

### OBJECT OF INVENTION

Therefore, it is an object of the present invention to provide a system configuration derivation device and a system configuration derivation method that can derive a system configuration that reflects the design tendency of an external design device that restricts the problem to be handled, which solves the above-mentioned problem.

### Solution to Problem

In one aspect of the present invention, a system configuration derivation device includes an actualization unit which actualizes abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

In another aspect of the present invention, a system configuration derivation method actualizes abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

In another aspect of the present invention, a non-transitory computer-readable capturing medium having captured therein a system configuration derivation program, when executed by a computer, stores the system configuration derivation program which actualizes abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

### Advantageous Effects of Invention

According to the present invention, it is possible to derive a system configuration that reflects the design tendency of the external design device that restricts the problem to be handled.

### BRIEF DESCRIPTION OF DRAWINGS

FIG. 1 is a block diagram showing a configuration example of the system configuration derivation device of the first example embodiment according to the present invention.

FIG. 2 is an explanatory diagram showing an example of an abstract configuration.

FIG. 3 is an explanatory diagram showing an example of hint information assigned to an abstract configuration.

FIG. 4 is an explanatory diagram showing an example of the input and output of an external design device.

FIG. 5 is an explanatory diagram showing an example of two actualization rules.

FIG. 6 is a flowchart showing the operation of the actualization configuration derivation process by the system configuration derivation device 100 of the first example embodiment.

FIG. 7 is an explanatory diagram showing an example of a search tree generated by the configuration information actualization unit 101.

FIG. 8 is an explanatory diagram showing an example of the actualization rules used to update the search tree.

FIG. 9 is a flowchart showing the operation of the actualization policy selection process by the actualization policy judgment unit 102 of the first example embodiment.

FIG. 10 is a flowchart showing the operation of the hint information assignment process by the external design information assignment unit 104 of the first example embodiment.

FIG. 11 is a flowchart showing the operation of the similarity score computation process by the external design information reflection unit 103 of the first example embodiment.

FIG. 12 is a block diagram showing a configuration example of the system configuration derivation device of the second example embodiment according to the present invention.

FIG. 13 is a flowchart showing the operation of the actualization policy selection process by the second actualization policy judgment unit 107 of the second example embodiment.

FIG. 14 is a block diagram showing a configuration example of the system configuration derivation device of the third example embodiment according to the present invention.

FIG. 15 is a flowchart showing the operation of the actualization configuration derivation process by the system configuration derivation device 120 of the third example embodiment.

FIG. 16 is a flowchart showing the operation of the actualization policy selection process by the third actualization policy judgment unit 10A of the third example embodiment.

FIG. 17 is a flowchart showing the operation of the additional actualization rule list generation process by the third actualization policy judgment unit 10A of the third example embodiment.

FIG. 18 is a block diagram showing a configuration example of the system configuration derivation device of the fourth example embodiment according to the present invention.

FIG. 19 is an explanatory diagram showing an example of the hardware configuration of an information processing device capable of realizing the system configuration derivation device of each example embodiment according to the present invention.

### DESCRIPTION OF EMBODIMENTS

### Example Embodiment 1

[Description of Configuration]

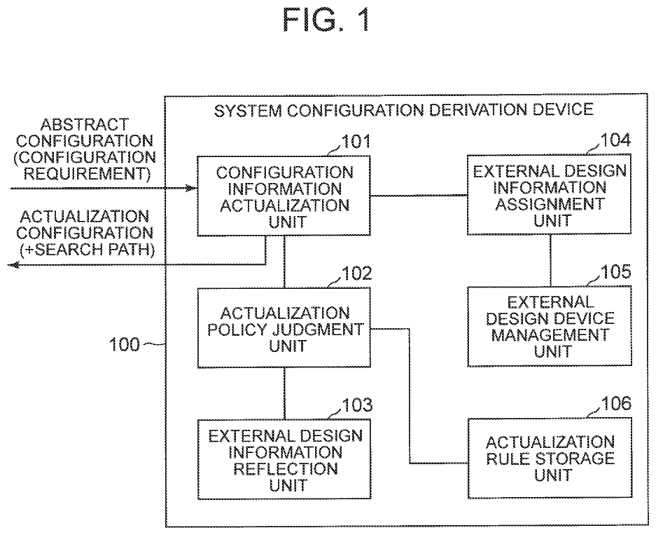

Hereinafter, example embodiments of the present invention are described with reference to the drawings. FIG. 1 is a block diagram showing a configuration example of the system configuration derivation device of the first example embodiment according to the present invention.

The system configuration derivation device of this example embodiment applies predefined rewriting rules to abstract system configuration information that includes unconfirmed portion regarding configuration and settings, which are specified in the form of attributed graphs and constraints related to attributed graphs. By applying the rules, the system configuration derivation device derives system configuration information that does not include the unconfirmed portion.

In addition, the system configuration derivation device of this example embodiment compares the result of processing the abstract configuration using an external design device with the original abstract configuration, and reflects the comparison result in the actualization method of the abstract configuration. This system configuration derivation device of this example embodiment can design an ICT system with the same quality as that which can be designed by existing domain-specific automatic design devices using a generic automatic design method.

The system configuration derivation device of this example embodiment performs generic automatic system design in the same way as the generic automatic system design technology described in NPL 1. The system configuration derivation device of this example embodiment is characterized by embedding existing external optimal design software or automatic design software, and using the embedded software in the design process.

By using the output of an embeddable external design device as a hint, the system configuration derivation device of this example embodiment can output a system configuration that reflects such as the capabilities and design tendencies of the external design device.

As shown in FIG. 1, the system configuration derivation device 100 of this example embodiment comprises a configuration information actualization unit 101, an actualization policy judgment unit 102, an external design information reflection unit 103, an external design information assignment unit 104, an external design device management unit 105, and an actualization rule storage unit 106.

The configuration information actualization unit 101 has the function of receiving an abstract configuration as input and deriving an actualization configuration by sequentially applying applicable actualization rules to the received abstract configuration.

The actualization policy judgment unit 102 receives a set of abstract configurations from the configuration information actualization unit 101 as input. After receiving them, the actualization policy judgment unit 102 has the function of selecting one or more sets including the following three items to be used in the next actualization by the configuration information actualization unit 101: “abstract configuration,” “actualization rule,” and “the part of the abstract configuration to be actualized by the actualization rule (hereinafter referred to as the actualization target)”.

The actualization rule storage unit 106 has the function of storing the actualization rules used in actualization. The actualization policy judgment unit 102 obtains the actualization rules to be selected from the actualization rule storage unit 106.

The external design information assignment unit 104 receives an abstract configuration from the configuration information actualization unit 101 as input. The external design information assignment unit 104 has the function of actualizing a part of the received abstract configuration by using an external design device. The external design information assignment unit 104 assigns the result of the actualization as hint information to the original abstract configuration.

The external design device management unit 105 has the function of managing the sets including the four “external design device,” “input subgraph extraction filter,” “input converter,” and “output converter” together. The input subgraph extraction filter is a filter that extracts only the information that can be input to the external design device from the abstract configuration.

The input converter is a converter that converts the information extracted by the input subgraph extraction filter from the abstract configuration into the input format of the external design device. The output converter is also a converter that converts the output of the external design device into the abstract configuration.

In addition, the external design device management unit 105 retrieves a set of data including the above four using an identifier corresponding to the external design device.

The external design information reflection unit 103 receives the abstract configuration from the actualization policy judgment unit 102 as input. The external design information reflection unit 103 has the function of computing a score (hereinafter referred to as the similarity score) that quantifies the closeness (similarity) to the design given by the external design device on the basis of the hint information assigned to the abstract configuration by the external design information assignment unit 104.

The abstract configuration and the data structure of the abstract configuration in this example embodiment are described below. As mentioned above, an abstract configuration is an abstract system configuration that includes unconfirmed portion regarding configuration and settings. The abstract configuration also plays a role in specifying the desired ICT system.

In other words, an abstract configuration is a configuration generated by an entity that desires an ICT system, describing only the information that has been confirmed (i.e., information that represents “the requirements that the system should meet and the functions that the system should have”), without any specific reference to the details of the system.

The basic structure of an abstract configuration is a graph consisting of “nodes”, which correspond to system functions, logical or physical components, and “edges”, which represent the relationship between two nodes when stretched between them.

Edges have an orientation. For an edge from node A to node B, node A is referred to as the “connection source” and node B is referred to as the “connection destination”. In the following, when nodes and edges are referred to without distinction, they are collectively referred to as “entity”.

An entity has an “identifier” that uniquely identifies the entity throughout the system, “type information” that represents the concept that the entity corresponds to, and “attribute information” that indicates information associated with the entity.

Attribute information is a group of sets including two “attribute names” and “attribute values”. A node may also have information indicating “parts to be requested”. A node may have information indicating multiple “parts to be requested”, or may not have any at all. In other words, the basic structure of an abstract configuration is a kind of general “attributed graph” structure.

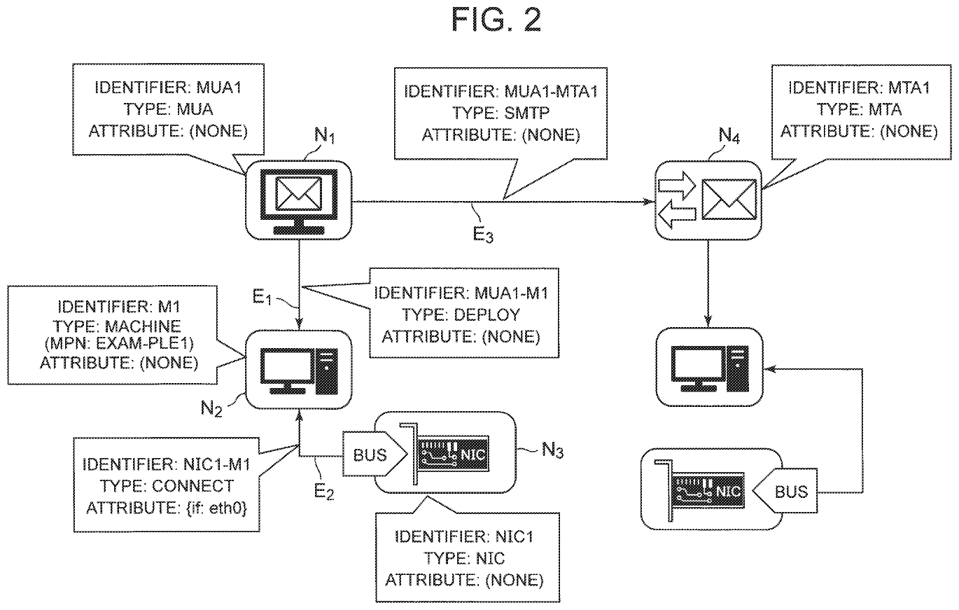

FIG. 2 is an explanatory diagram showing an example of an abstract configuration. The rounded corner rectangles surrounding the icons shown in FIG. 2 represent nodes. FIG. 2 shows a plurality of nodes, including four nodes from N₁ to N₄.

The arrows between the nodes shown in FIG. 2 represent edges. FIG. 2 shows multiple edges, including three edges from E₁ to E₃.

Some of the entities shown in FIG. 2 are also shown with accompanying callouts. The information in the callouts shown in FIG. 2 represents information of identifier, type, and attribute that the accompanying entities have. In the example shown in FIG. 2, callouts have been omitted for some entities for simplicity of explanation.

Node N₁ represents a MUA (Mail User Agent). However, the software that is supported as an MUA is not specified in node N₁.

Node N₂ is a physical machine. As shown in FIG. 2, the model number “EXAM-PLE1” is set for node N₂. In other words, node N₂ is a node that fully corresponds to a concrete product.

Node N₃ represents a NIC (Network Interface Card). Similar to node N₂, node N₃ corresponds to a concrete product.

In addition, node N₃ is labeled with the arrow-shaped label “BUS”. The arrow-shaped label represents the component that node N₃ is requesting. In other words, the arrow-shaped label represents the request that “the NIC must be physically connected to the computer bus in order to use its functions”. As described below, in the example shown in FIG. 2, the requirement represented by the arrow-shaped label is satisfied.

Node N₄ represents the MTA (Mail Transfer Agent). However, the software that is supported as an MTA is not specified in node N₄.

Edge E₁ represents that node N₁ of the connection source is deployed to node N₂ of the connection destination.

Edge E₂ represents that node N₃ of the connection source is physically connected to node N₂ of the connection destination. With edge E₂, the request imposed on node N₃ is satisfied.

In addition, the attribute value “eth0” is set for the attribute “if” in edge E₂. The attribute “if” represents the network interface. In other words, the attribute “if” indicates that edge E₂ is connected to the network interface “eth0” of node N₂ of the connection destination.

Edge E₃ represents that node N₁ of the connection source communicates with node N₄ of the connection destination via SMTP (Simple Mail Transfer Protocol).

To summarize the above, the abstract configuration shown in FIG. 2 is a partially unconfirmed representation of a system that realizes a series of mechanisms in which a user of a desktop PC (Personal Computer) queries a mail server via an MUA and the mail server forwards the mail via an MTA.

In addition to the above structure, two pieces of information, “inter-attribute constraints” and “hint information”, may be assigned to the abstract structure. A plurality of “inter-attribute constraints” and “hint information” may be assigned, or may not be assigned at all.

Inter-attribute constraints are constraints imposed on the attribute values of an abstract configuration. An abstract configuration is taken to represent a system configuration that satisfies all the inter-attribute constraints assigned to it.

The hint information indicates a set (G, G′) that includes two graphs: a subgraph G of an abstract configuration represented as an attributed graph, and another graph G′ such that all the nodes included in the subgraph G are included.

The hint information indicating (Cc G′) is assigned to the abstract configuration by the external design information assignment unit 104. The hint information is information that gives a hint of the actualization policy of the abstract configuration being assigned, such as “the subgraph G, when actualized, should have a configuration similar to the graph G′”.

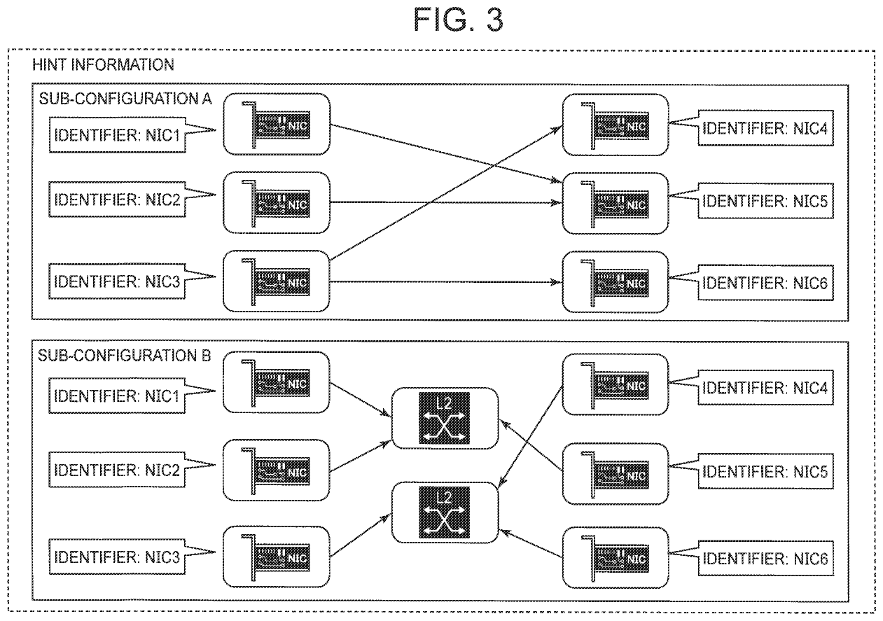

FIG. 3 is an explanatory diagram showing an example of hint information assigned to an abstract configuration. The hint information shown in FIG. 3 includes sub-configuration A and sub-configuration B.

The sub-configuration A shown in FIG. 3 is represented by a subgraph showing six “NIC” type nodes, node NIC1, node NIC2, . . . , node NIC6, connected to other nodes by “TCP (Transmission Control Protocol)” type edges.

The sub-configuration B shown in FIG. 3 is represented by a subgraph showing six “NIC” type nodes, node NIC1, node NIC2, . . . , node NIC6, connected to other nodes via L2 switches. The sub-configuration B including two L2 switches is a specific configuration.

The sub-configuration B shown in FIG. 3 can be considered to represent one of the optimal communication network configurations that connect six NIC-type nodes so that there is no communication (except for the reverse direction connection) between nodes other than that specified in sub-configuration A shown in FIG. 3.

Therefore, giving sub-configuration B as a hint to the structure of sub-configuration A means letting the configuration information actualization unit 101 aim to design the optimal communication network configuration.

The following describes the input subgraph extraction filter, input converter, and output converter associated with the external design device managed by the external design device management unit 105 of this example embodiment, respectively.

The input subgraph extraction filter of the external design device f is a filter that, when applied to an abstract configuration, can extract subgraphs that consist only of entities with types that can be handled by the external design device f. The attribute “can be handled by external design device f” is given in advance for the target type.

The input converter of the external design device f is a converter that can convert an abstract configuration into data in the input format of the corresponding external design device f.

The output converter of the external design device f is a converter that can convert the data in the output format of the external design device f into the corresponding abstract configuration.

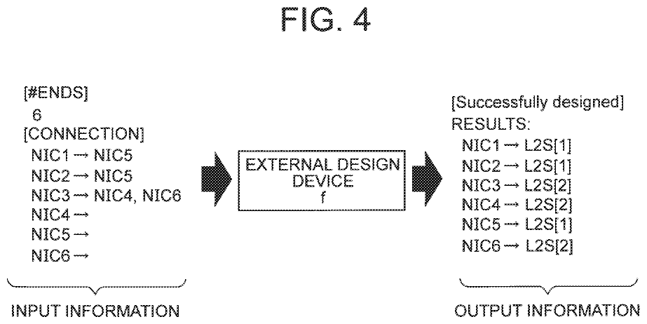

Specific examples of conversion by the input converter and by the output converter are shown below. FIG. 4 is an explanatory diagram showing an example of the input and output of an external design device.

The input information shown in FIG. 4 is the input information of the external design device f. The input information shown in FIG. 4 is the information corresponding to the sub-configuration A shown in FIG. 3.

The external design device f shown in FIG. 4 is a device that receives the number of nodes and end to end connection information as input and outputs an actualized communication network configuration.

The output information shown in FIG. 4 is the output information of the external design device f. The output information shown in FIG. 4 is the information corresponding to the sub-configuration B shown in FIG. 3. In the output information shown in FIG. 4, the information of the actualized communication network configuration is represented as an actualized connection relationship between two nodes (terminal node and intermediate node).

In other words, the input converter of the external design device f shown in FIG. 4 is such a converter that outputs the input information shown in FIG. 4 after receiving the sub-configuration A shown in FIG. 3. The output converter of the external design device f shown in FIG. 4 is such a converter that outputs the sub-configuration B shown in FIG. 3 after receiving the output information shown in FIG. 4.

Next, the actualization rules in this example embodiment are described. The actualization rule includes information that indicates the target of the actualization, information that indicates the configuration after the actualization, and inter-attribute constraints of the additional target.

Hereinafter, the information that indicates the target of the actualization is referred to as the left side (of the actualization rule). The information that indicates the configuration after the actualization is referred to as the right side (of the actualization rule). The inter-attribute constraints of the additional target are referred to as the additional constraint (of the actualization rule).

The left side of an actualization rule and the right side of an actualization rule are represented by an attributed graph, just like the basic structure of an abstract configuration. The additional constraints of an actualization rule are identical to the inter-attribute constraints that are the assignment information of the abstract configuration. The additional constraint of an actualization rule is a constraint on the attributed graph that represents the right side of the actualization rule.

The following is an example of how an abstract configuration can be actualized by an actualization rule.

When a structure corresponding to the left side of an actualization rule R is included in an abstract configuration D, the actualization rule R is applicable to the abstract configuration D. “Having a corresponding structure” means that there is a one-to-one corresponding node and a one-to-one corresponding edge.

However, “edge Ea corresponds to edge E_{b}” does not just mean that the edges on type information and attributes alone correspond, but also that the nodes on both ends are corresponding nodes.

For example, if edge Ea is an edge stretched from node Nₐ to node N_{b}, and edge E_{b} is an edge stretched from node N_{c} to node Nₐ, then if edge Ea corresponds to edge E_{b}, then node Nₐ and node N_{c} and node N_{b} and node Nₐ are the corresponding nodes.

As mentioned above, the substructure of an abstract configuration D that corresponds to the left side of the actualization rule R is referred to as the actualization target of the abstract configuration D by the actualization rule R.

That is, when an actualization rule R is applicable to an abstract configuration D, the abstract configuration D has a substructure, i.e., actualization target, that corresponds one-to-one to the left side of the actualization rule R.

The rewriting of the abstract configuration D by the actualization rule R is to replace the actualization target with the structure represented by the right side of the actualization rule R. In the rewriting, if there is an entity in the right side that has an identifier in common with an entity in the left side of the actualization rule R, the entity in the left side is directly replaced by the entity in the right side.

If there is no entity on the right side that has an identifier in common with an entity on the left side of the actualization rule R, a new corresponding entity is generated.

If the actualization rule R includes additional constraints, the corresponding inter-attribute constraints are added to the abstract configuration D in addition to the rewriting of the basic structure described above.

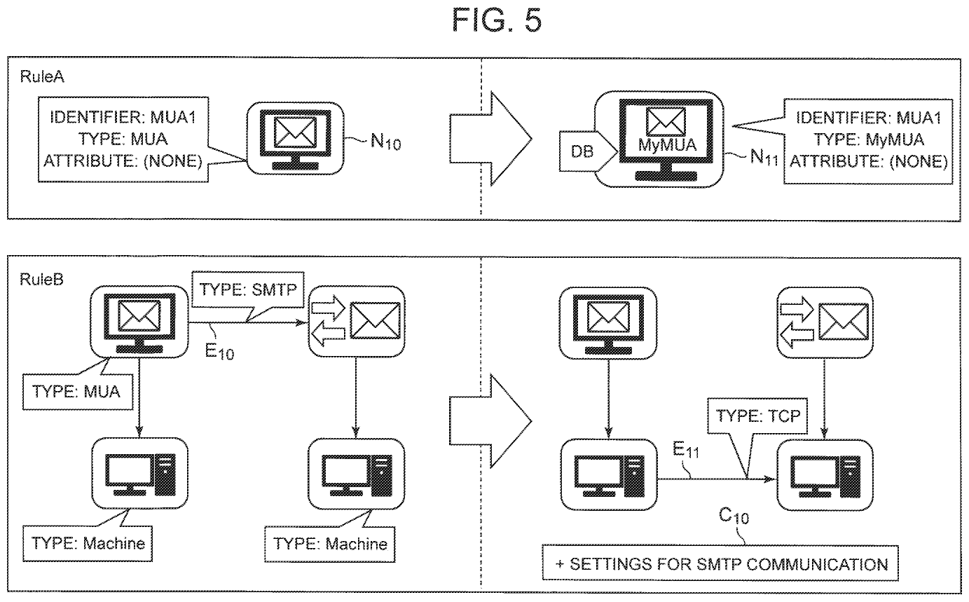

The following are actualization rules and specific examples of rewriting by actualization rules. FIG. 5 is an explanatory diagram showing an example of two actualization rules.

RuleA, shown in FIG. 5, is an actualization rule that conforms to a node of type MUA, which is an abstract type, and actualizes a node of type MUA into a node of type MyMUA, which is an actualized type.

Node N₁₀ on the left side and node N₁₁ on the right side of RuleA shown in FIG. 5 are the same node. In other words, node N₁₀ and node N₁₁ are the same node with the same identifier, only the type has been changed. From the left side to the right side, a node is removed and another node is not newly added.

In other words, the rewriting of the abstract configuration by RuleA shown in FIG. 5 includes the operation of changing the node type of the MUA-type.

Also shown in FIG. 5, RuleB is an actualization rule that actualizes edge E₁₀, which represents SMTP communication between the MUA and MTA, into edge E₁₁, which represents TCP communication between the machines where the MUA or MTA is deployed, and appropriate settings C₁₀.

In other words, the rewriting of the abstract configuration by RuleB shown in FIG. 5 includes the operation to delete of the SMTP-type edge E₁₀ between the MUA-type node and the MTA-type node, and to add a TCP-type edge E₁₁ between the Machine-type nodes, each of which is connected by a Deploy-type edge. It also includes the operation to add the inter-attribute constraint (C₁₀) concerning the setting for SMTP communication.

Next, the actualization configuration derived by the system configuration derivation device 100 of this example embodiment is described.

An actualization configuration in this example embodiment means an abstract configuration that has been fully actualized. In this example embodiment, an abstract configuration is considered to be fully actualized when all of the following three conditions (Condition 1, Condition 2, and Condition 3) are satisfied.

“Condition 1: All node types included in the abstract configuration must be an actualized type”

Whether or not the node type is actualized is defined in advance as an attribute to the type.

“Condition 2: All edge types included in the abstract configuration must be an actualized type”

Whether or not the edge type is actualized is defined in advance as an attribute to the type.

“Condition 3: For all nodes included in the abstract configuration, the requested component must be connected at the appropriate edge”

An abstract configuration that satisfies all three of the above conditions is an actualization configuration that includes no unconfirmed elements other than attribute values. Therefore, an actualization configuration represents a configuration that can be operated as an ICT system by being assigned appropriate setting values according to the assigned attribute value constraints.

For example, the abstract configuration shown in FIG. 2 is not fully actualized because it does not satisfy Conditions 1 and 2 above.

Specifically, nodes N₁ and N₄ shown in FIG. 2 violate Condition 1 because they are not nodes of the type corresponding to concrete software, as described above.

Also, edge E₃ shown in FIG. 2 violates Condition 2 because it is not an edge that shows a specific method of communication by SMTP.

Of the nodes shown in FIG. 2, only node N₃ has the requested parts set. As mentioned above, the request imposed on node N₃ has been satisfied, so Condition 3 is satisfied at this time.

However, if, for example, node N₁ is actualized by RuleA shown in FIG. 5, the type of node N₁ is converted to MyMUA. Since a node of type MyMUA includes the requested parts, Condition 3 may not be satisfied if node N₁ is actualized by RuleA.

[Description of Operation]

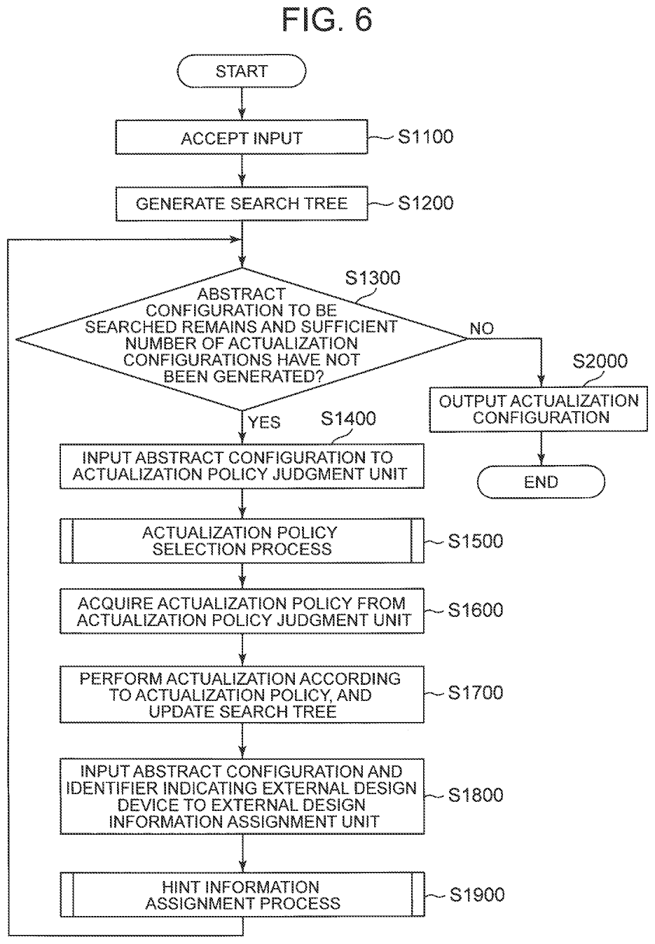

Hereinafter, the operation of the system configuration derivation device 100 of this example embodiment is described with reference to FIGS. 6 to 11.

First, the operation of the system configuration derivation device 100 of this example embodiment to design an ICT system is described with reference to FIG. 6. FIG. 6 is a flowchart showing the operation of the actualization configuration derivation process by the system configuration derivation device 100 of the first example embodiment.

First, the configuration information actualization unit 101 accepts input of configuration requirements represented in the form of an abstract configuration from the input/output device (step S1100).

Next, the configuration information actualization unit 101 generates a search tree whose root is the abstract configuration accepted in step S1100 (step S1200).

Next, the configuration information actualization unit 101 checks whether or not the abstract configuration to be searched remains in the search tree and whether or not a sufficient number of actualization configurations have not been generated (step S1300). The number of targets for generating actualization configurations is specified, for example, via an input/output device. Alternatively, the number of targets for generating actualization configurations is embedded into the system configuration derivation device 100 from the beginning.

If there are still abstract configurations to be searched for in the search tree and a sufficient number of actualization configurations have not been generated (Yes in step S1300), the configuration information actualization unit 101 updates the generated search tree by repeatedly executing the following three steps. By updating the search tree, the configuration information actualization unit 101 derives the actualization configuration.

First, the configuration information actualization unit 101 gives all abstract configurations in the search tree that have not been completely actualized and still have an executable actualization policy for the abstract configuration as input to the actualization policy judgment unit 102 (step S1400). After the abstract configurations are input, the actualization policy judgment unit 102 executes the actualization policy selection process (step S1500).

After the actualization policy selection process is executed, the configuration information actualization unit 101 receives the actualization policy that is the output of the actualization policy judgment unit 102 (step S1600). As described above, the actualization policy includes the abstract configuration D to be actualized next, the actualization rule R to actualize the abstract configuration D, and the actualization target a to be rewritten by the actualization rule R.

Next, the configuration information actualization unit 101 performs actualization according to all the actualization policies obtained in step S1600. When an abstract configuration D′ is obtained as a result of the actualization according to the actualization policy (D, R, a), the configuration information actualization unit 101 adds the abstract configuration D′ as a child element of the abstract configuration D in the search tree (step S1700).

After actualization, the configuration information actualization unit 101 records the information “Actualization by actualization policy (D, R, a) has been executed” in the search tree for the processing of step S1700.

Next, the configuration information actualization unit 101 assigns hint information to some of the abstract configurations obtained in step S1700. If it is determined that the abstract configuration D′ is required to be assigned with hint information by an external design device f, the configuration information actualization unit 101 inputs the abstract configuration D′ and an identifier indicating the external design device f to the external design information assignment unit 104 (step S1800).

The external design information assignment unit 104, in which the abstract configuration D′ and the identifier indicating the external design device f are input, executes the hint information assignment process (step S1900). After the hint information assignment process is executed, the configuration information actualization unit 101 performs the process of step S1300.

In step S1800, if the configuration information actualization unit 101 determines that the abstract configuration is required to be assigned hint information, for example, it is the following case.

For example, consider the case where some of the entity types are assigned two types of flag information: the first flag that says “target to design using the external design device f”, and the second flag that says “some of the parts to be requested are target to design using the external design device f”.

When the abstract configuration includes a type with the first flag for the external design device f and does not include a type with the second flag for the external design device f, the configuration information actualization unit 101 assigns hint information using the external design device f to the abstract configuration.

The above example is an example of the criteria for determining whether or not to assign hint information to an abstract configuration. The criteria for determining whether or not to assign hint information used by the configuration information actualization unit 101 of this example embodiment is not limited to the above example.

If there are no abstract configurations left in the search tree to be searched, or if a sufficient number of actualization configurations have been generated (No in step S1300), the configuration information actualization unit 101 outputs the obtained actualization configuration to the input/output device as a result of the actualization configuration derivation process (step S2000). After outputting the actualization configuration, the system configuration derivation device 100 terminates the actualization configuration derivation process of the system.

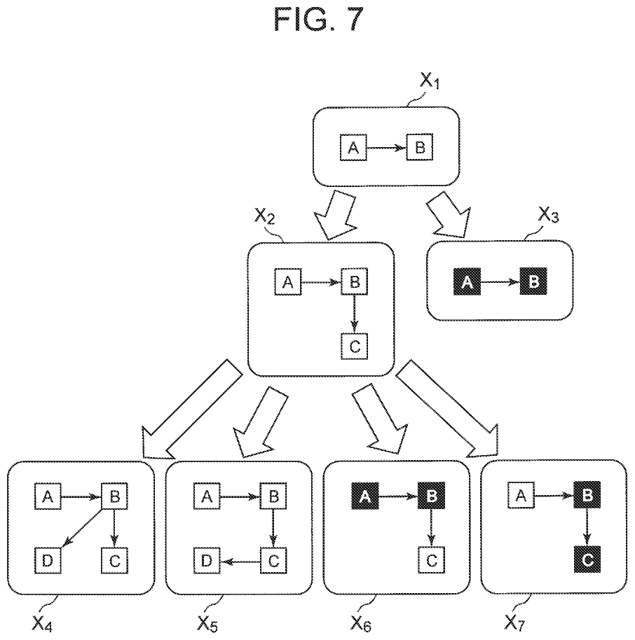

FIG. 7 is an explanatory diagram showing an example of a search tree generated by the configuration information actualization unit 101. From X₁ to X₇ shown in FIG. 7 are the abstract configurations that make up the search tree.

For simplicity of explanation, the node types shown in FIG. 7 are assumed to be two types with no particular meaning. That is, the nodes included in the abstract configuration shown in FIG. 7 are limited to either “Abs” type nodes, which are represented by white rectangles, or “Con” type nodes, which are represented by black rectangles.

Of the two node types, the Abs type is an abstract type, and the Con type is an actualized type. Both types do not require any parts.

For simplicity of explanation, only one edge type is shown in FIG. 7. The edge types are actualized.

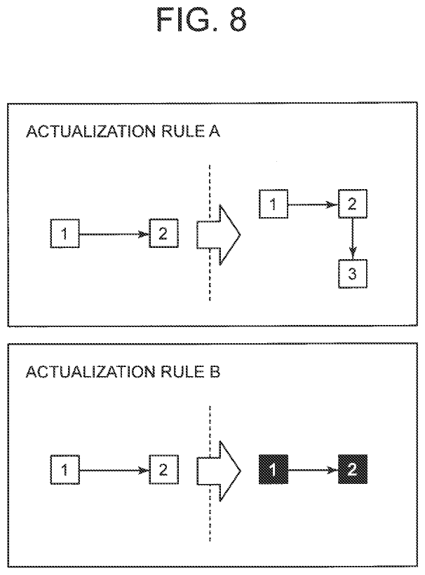

FIG. 8 is an explanatory diagram showing an example of the actualization rules used to update the search tree. For simplicity of explanation, the actualization rules used to update the search tree are also limited to two rules, actualization rule A and actualization rule B, which have no particular meaning.

As shown in FIG. 8, actualization rule A is a rule that adds Abs type node 3 and an edge stretched from Abs type node 2 to Abs type node 3 to an abstract configuration that includes Abs type node 1, Abs type node 2, and an edge stretched from Abs type node 1 to Abs type node 2.

Also as shown in FIG. 8, actualization rule B is a rule that changes each node type to Con type in an abstract configuration that includes Abs type node 1, Abs type node 2, and edges stretched from Abs type node 1 to Abs type node 2.

X₁ shown in FIG. 7 is an abstract configuration corresponding to the configuration requirements given by the input/output device. In the abstract configuration X₁, the two Abs type nodes are connected to each other by one edge.

The configuration information actualization unit 101 can derive two child elements from the abstract configuration X₁: the abstract configuration X₂ and the abstract configuration X₃.

The abstract configuration X₂ is a child element obtained as a result of applying actualization rule A to the abstract configuration X₁. The abstract configuration X₃ is a child element obtained as a result of applying actualization rule B to the abstract configuration X₁.

The abstract configuration X₃, which includes only nodes of type Con, is an actualization configuration. If the situation is such that finding one actualization configuration satisfies the termination condition, the configuration information actualization unit 101 terminates the procedure of updating the search tree when the actualization configuration is generated.

The configuration information actualization unit 101 can further derive four child elements from the abstract configuration X₂: the abstract configuration X₄, the abstract configuration X₅, the abstract configuration X₆, and the abstract configuration X₇.

The abstract configuration X₄ and X₅ are both child elements obtained as a result of applying actualization rule A to the abstract configuration X₂. However, the actualization target of the actualization is different between the abstract configuration X₄ and the abstract configuration X₅.

In other words, the abstract configuration X₄ is a child element that is generated when the configuration information actualization unit 101 corresponds node A to node 1 of actualization rule A and node B to node 2 of actualization rule A. The abstract configuration X₅ is also a child element generated when the configuration information actualization unit 101 corresponds node B to node 1 of actualization rule A and node C to node 2 of actualization rule A. Note that the abstract configuration X₄ and the abstract configuration X₅ are still configurations to which the actualization rules can be applied.

Both the abstract configuration X₆ and the abstract configuration X₇ are child elements obtained as a result of applying actualization rule B to the abstract configuration X₃. However, the actualization target of the actualization is different between the abstract configuration X₆ and the abstract configuration X₇.

In other words, the abstract configuration X₆ is a child element that is generated when the configuration information actualization unit 101 corresponds node A to node 1 of actualization rule B and node B to node 2 of actualization rule B. The abstract configuration X₇ is also a child element generated when the configuration information actualization unit 101 corresponds node B to node 1 of actualization rule B and node C to node 2 of actualization rule B.

Although both the abstract configuration X₆ and X₇ are not yet actualization configurations, it is impossible to proceed with the search starting from the abstract configuration X₆ and X₇.

Therefore, if the configuration information actualization unit 101 continues the procedure to obtain an actualization configuration other than the abstract configuration X₃, it inputs the abstract configuration X₄ and X₅ to the actualization policy judgment unit 102 in step S1400, and asks the actualization policy judgment unit 102 for the next actualization to be executed.

Next, the operation of the actualization policy judgment unit 102 of this example embodiment is described. As described above, the actualization policy judgment unit 102 of this example embodiment selects abstract configurations, actualization rules, and actualization targets in abstract configurations, respectively.

As described above, the actualization policy judgment unit 102 of this example embodiment receives as input a set of abstract configurations that have not been fully actualized from the configuration information actualization unit 101. Next, the actualization policy judgment unit 102 selects one or more sets (D, R, a) including three components that are abstract configuration D, actualization rule R, and actualization target a, which are considered to be the targets of the next actualization. Next, the actualization policy judgment unit 102 inputs the selected sets to the configuration information actualization unit 101.

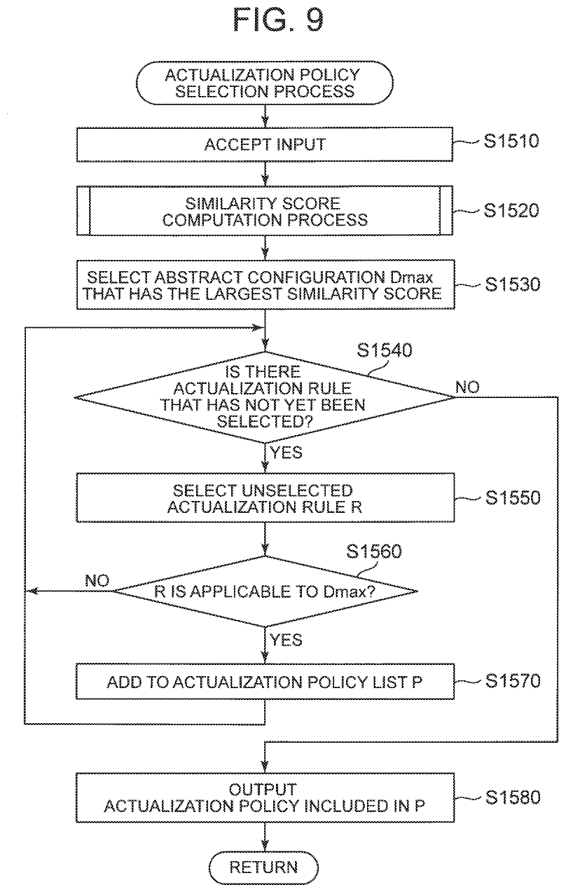

The operation of the actualization policy judgment unit 102 of this example embodiment to select the actualization policy is described with reference to FIG. 9. FIG. 9 is a flowchart showing the operation of the actualization policy selection process by the actualization policy judgment unit 102 of the first example embodiment. The actualization policy selection process shown in FIG. 9 is the process of step S1500 shown in FIG. 6.

First, the actualization policy judgment unit 102 receives a set of abstract configurations as input from the configuration information actualization unit 101 (step S1510).

Next, the actualization policy judgment unit 102 inputs all the abstract configurations included in the input to the external design information reflection unit 103. The external design information reflection unit 103 with the input of the abstract configurations performs the similarity score computation process (step S1520).

After the similarity score computation process is executed, the actualization policy judgment unit 102 receives the similarity score computed in step S1520 from the external design information reflection unit 103. The actualization policy judgment unit 102 selects one abstract configuration Dmax that has the largest similarity score among the received similarity scores (step S1530).

Next, the actualization policy judgment unit 102 retrieves one set of actualization rules managed in the actualization rule storage unit 106. The actualization policy judgment unit 102 checks whether there is an actualization rule that has not yet been selected among the retrieved sets (step S1540).

If there is an actualization rule that has not yet been selected (Yes in step S1540), the actualization policy judgment unit 102 selects the unselected actualization rule as R (step S1550). The actualization policy judgment unit 102 may select an actualization rule R from the entire set of actualization rules retrieved from the actualization rule storage unit 106, or may select an actualization rule R according to some criteria.

Next, the actualization policy judgment unit 102 checks whether the selected actualization rule R is applicable to the abstract configuration Dmax or not (step S1560). If it is not applicable (No in step S1560), the actualization policy judgment unit 102 returns to step S1540.

If it is applicable (Yes in step S1560), the actualization policy judgment unit 102 enumerates one or more configurations a that can be selected as actualization targets, and adds the actualization policy (Dmax, R, a) to the actualization policy list P (step S1570). After the addition, the actualization policy judgment unit 102 returns to step S1540.

If there are multiple configurations that can be selected as the actualization target, i.e., if there are multiple methods for selecting the configuration corresponding to the left side of the actualization rule R, the actualization policy judgment unit 102 may select all of the selectable configurations. Alternatively, the actualization policy judgment unit 102 may select any configuration among the selectable configurations according to some criteria.

When the processing of step S1550 to step S1570 is executed for all selectable actualization rules (No in step S1540), the actualization policy judgment unit 102 outputs all actualization policies included in the actualization policy list P (step S1580). After outputting, the actualization policy judgment unit 102 returns to the actualization configuration derivation process.

Next, the operation of the external design information assignment unit 104 of this example embodiment is described. As described above, the external design information assignment unit 104 of this example embodiment receives an abstract configuration D from the actualization policy judgment unit 102 as input, and actualizes the received abstract configuration D using an external design device. Next, the external design information assignment unit 104 assigns the result of the actualization to the abstract configuration D as hint information.

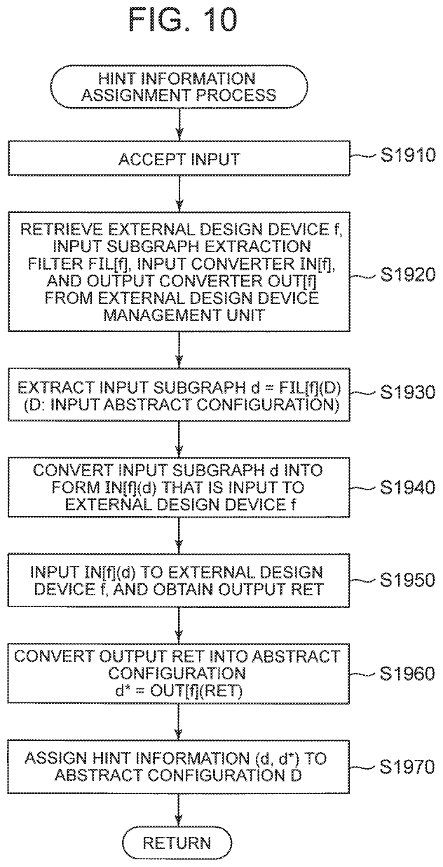

The operation in which the external design information assignment unit 104 of this example embodiment to actualize the abstract configuration D using the external design device f and output hint information is described with reference to FIG. 10. FIG. 10 is a flowchart showing the operation of the hint information assignment process by the external design information assignment unit 104 of the first example embodiment. The hint information assignment process shown in FIG. 10 is the processing of step S1900 shown in FIG. 6.

First, the external design information assignment unit 104 accepts as input the abstract configuration D and an identifier indicating the external design device f to be used (step S1910).

Next, the external design information assignment unit 104 retrieves the external design device f and the associated input subgraph extraction filter FIL[f], input converter IN[f], and output converter OUT[f], respectively, from the external design device management unit 105 using the input identifier (step S1920).

Next, the external design information assignment unit 104 extracts the input subgraph d, which is the subgraph of the abstract configuration D corresponding to the actualization target of the external design device f, using the input subgraph extraction filter FIL[f] for the abstract configuration D (step S1930). The input subgraph d is obtained by the following Equation (1).

d=FIL[f](D) Equation (1)

Next, the external design information assignment unit 104 converts the input subgraph d into a form IN[f](d) that can be input to the external design device f by applying the input converter IN[f] to the input subgraph d (step S1940).

Next, the external design information assignment unit 104 inputs the IN[f](d) obtained in step S1940 to the external design device f and obtains the output RET from the external design device f (step S1950).

Next, the external design information assignment unit 104 obtains the abstract configuration d* by applying the output converter OUT[f] to the output RET obtained in step S1950 (step S1960). The abstract configuration d* is obtained by the following Equation (2).

d*=OUT[f](RET) Equation (2)

Next, the external design information assignment unit 104 assigns hint information (d, d*) to the input abstract configuration D (step S1970). After assigning, the external design information assignment unit 104 returns to the actualization configuration derivation process.

Next, the operation of the external design information reflection unit 103 of this example embodiment is described. As described above, the external design information reflection unit 103 of this example embodiment receives the abstract configuration D as input and assigns a similarity score based on the hint information assigned to the abstract configuration D.

As described above, one abstract configuration may have any number of hint information assigned to it, zero or more. The following describes how the external design information reflection unit 103 of this example embodiment computes the similarity score for the hint information on the basis of one abstract configuration and one hint information assigned to the abstract configuration.

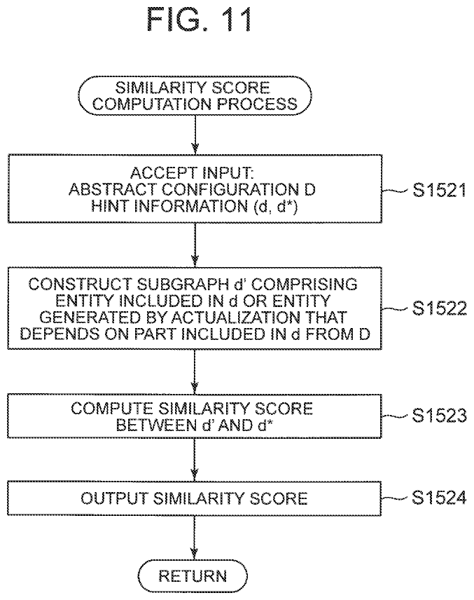

FIG. 11 is a flowchart showing the operation of the similarity score computation process by the external design information reflection unit 103 of the first example embodiment. The similarity score computation process shown in FIG. 11 is the process of step S1520 shown in FIG. 9.

The example shown in FIG. 11 is an example of computing the similarity score regarding the hint information (d, d*), which is assigned to the abstract configuration D. First, the external design information reflection unit 103 receives the abstract configuration D and the hint information (d, d*) as input (step S1521).

Next, the external design information reflection unit 103 constructs the subgraph d′ by extracting from the abstract configuration D the entities included in d and the entities generated by actualization that depend on the parts included in d (step S1522).

Note that actualization that depends on the entity ε means actualization in which the entity ε is included in the actualization target. Also, an entity generated by actualization is a newly generated entity because it was included only in the right side of the actualization rule.

Next, the external design information reflection unit 103 computes the similarity score as a graph between the abstract configuration d′ and the abstract configuration d* (step S1523). The external design information reflection unit 103 outputs the computed similarity score as a similarity score for the hint information (d, d*) (step S1524). After outputting the similarity score, the external design information reflection unit 103 returns to the actualization policy selection process.

The method of computing the similarity score of the abstract configuration d′ and the abstract configuration d* as graphs in step S1523 is, for example, the method of computing on the basis of the distance between graphs, commonly known as Graph Edit Distance (GED).

Specifically, it is possible to add the exact same structure as the abstract configuration d* to the abstract configuration d′ by performing the operations “add node” and “add edge” to the abstract configuration d′. The external design information reflection unit 103 can adopt 1/(1+min) as the similarity score, using the minimum value min of the number of operations required for addition (“I” denotes division).

For example, consider computing the similarity score for the hint information (d, d*) using the above method when the sub-configurations A and B shown in FIG. 3 are the abstract configuration d′ and the abstract configuration d*, respectively.

In order to transform the abstract configuration d′ into the abstract configuration d*, it is necessary to remove the edge indicating the connectivity between NICs in the abstract configuration d′ four times, to add the L2 switch twice, and to add the edge indicating the connection between NIC and L2 switch six times, respectively. In other words, a total of 12 operations are required, so the similarity score is computed as 1/(1+12)=1/13.

Another possible method to compute the similarity score is to simply count the number of nodes in d′ that are of the same type as the nodes in d*, and the number of edges in d′ that are of the same type as the edges in d*.

The method of computing the similarity score of the abstract configuration d′ and the abstract configuration d* as a graph in step S1523 is not limited to the above two methods. However, the methods that can be used are such that the computed similarity score is the maximum value when the abstract configuration d′ and the abstract configuration d* are similar.

Next, how the external design information reflection unit 103 assigns a similarity score to one abstract configuration is described. As mentioned above, one abstract configuration may have multiple hint information assigned to it, or none at all.

The external design information reflection unit 103, for example, computes the sum of the similarity scores obtained from the respective hint information as the similarity score of the abstract configuration. The method by which the external design information reflection unit 103 computes the similarity score of the abstract configuration from the similarity scores obtained from the respective hint information is not limited to the method described above.

For example, the external design information reflection unit 103 may use the average value, maximum value, etc. of the similarity scores obtained from the respective hint information as the similarity score of the abstract configuration. However, the external design information reflection unit 103 computes the similarity score to be a larger value when the abstract configuration is similar to all the configuration groups assigned as hint information or some configurations included in the configuration groups.

[Description of Effect]

The configuration information actualization unit 101 of the system configuration derivation device 100 of this example embodiment receives the input configuration requirements in the form of an abstract configuration. The configuration information actualization unit 101 repeatedly actualizes the abstract configuration on the basis of the actualization policy received from the actualization policy judgment unit 102, and outputs the configuration information of the ICT system that has been completely actualized.

In addition, the external design information assignment unit 104 of this example embodiment assigns hint information generated by external design devices registered in the external design device management unit 105 to the abstract configuration.

In addition, the actualization policy judgment unit 102 of this example embodiment selects the next abstract configuration to be actualized by referring to the similarity score computed by the external design information reflection unit 103 on the basis of the hint information assigned to the abstract configuration.

Therefore, the system configuration derivation device 100 of this example embodiment can derive an actualization configuration that is close to the optimal configuration for a specific domain computed by the external design device, because it preferentially searches for abstract configurations that are similar to the design results of the external design device. The system configuration derivation device 100 of this example embodiment can derive an actualization configuration of an ICT system that satisfies various system requirements and is close to the output of external specialized optimal design software or automatic design software.

### Example Embodiment 2

[Description of Configuration]

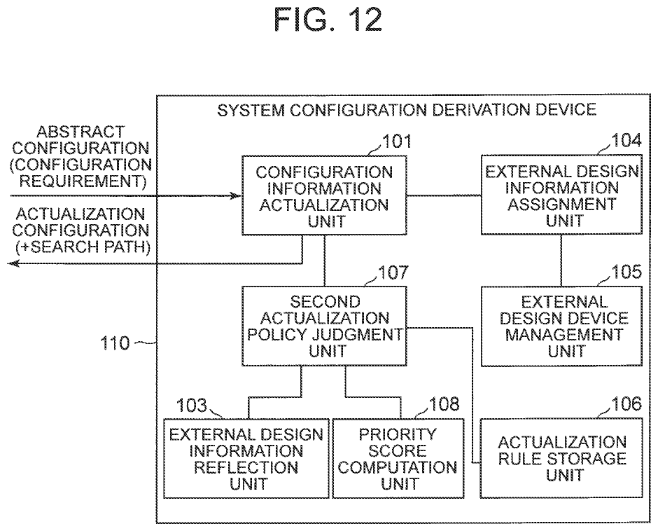

Next, the system configuration derivation device in the second example embodiment of the present invention is described with reference to the drawings. FIG. 12 is a block diagram showing a configuration example of the system configuration derivation device of the second example embodiment according to the present invention.

The system configuration derivation device 110 of this example embodiment differs from the system configuration derivation device 100 shown in FIG. 1 in that the actualization policy judgment unit 102 is replaced by a second actualization policy judgment unit 107.

The system configuration derivation device 110 also has a priority score computation unit 108. As shown in FIG. 12, the priority score computation unit 108 is connected to the second actualization policy judgment unit 107.

The configuration of the system configuration derivation device 110 of this example embodiment, other than the second actualization policy judgment unit 107 and the priority score computation unit 108, is the same as the configuration of the system configuration derivation device 100 of the first example embodiment. The system configuration derivation device 110 of this example embodiment operates in almost the same manner as the system configuration derivation device 100 of the first example embodiment, except for the operation of the second actualization policy judgment unit 107.

The priority score computation unit 108 of this example embodiment takes an abstract configuration as input and computes a priority score for the input abstract configuration. The priority score is a score given to the abstract configuration that the configuration information actualization unit 101 should search next on the basis of some index.

For example, the priority score computation unit 108 may return the reciprocal of the number of entities included in a given abstract configuration as the priority score. The priority score, which is the reciprocal of the number of entities, represents the size of the system. By having the configuration information actualization unit 101 preferentially search for an abstract configuration with a high priority score, it becomes easier to derive a system with fewer parts to be used.

For example, the priority score computation unit 108 may return as the priority score the reciprocal of the number of non-actualized entities, i.e., entities of abstract type, or the number of entities lacking the requested parts, included in the given abstract configuration.

By having the configuration information actualization unit 101 preferentially search for abstract configurations with high priority scores computed by the above method, it is expected that the search proceeds in such a way as to quickly reduce the number of unconfirmed elements in the abstract configuration.

The priority score returned by the priority score computation unit 108 of this example embodiment is not limited to the above two examples.

The second actualization policy judgment unit 107 of this example embodiment is responsible for responding to the actualization policy in response to the query of the configuration information actualization unit 101 in the same way as the actualization policy judgment unit 102. The second actualization policy judgment unit 107 uses, for example, the sum of the similarity score and the priority score as the integration score of the abstract configuration.

In addition, the second actualization policy judgment unit 107 uses, for example, a set including two scores that is a similarity score and a priority score as an integration score. When comparing the sizes of the two sets, the second actualization policy judgment unit 107 determines that the set with the larger similarity score is the larger set. If the similarity scores of the two sets are equal, the second actualization policy judgment unit 107 determines the largest integration score by determining the set with the larger priority score as the larger set.

The examples of the definition of the integration score by the second actualization policy judgment unit 107 are not limited to the above two examples.

[Description of Operation]

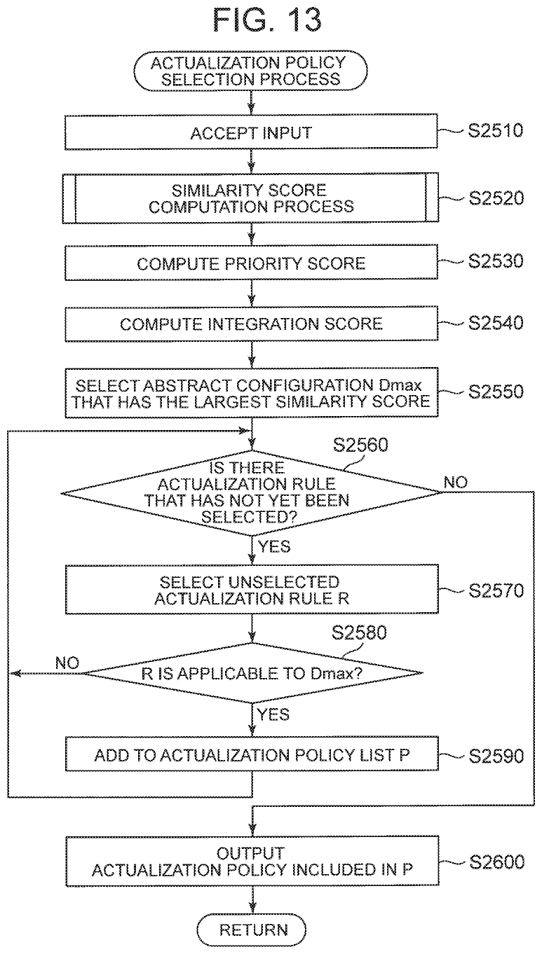

Hereinafter, the operation of the second actualization policy judgment unit 107 of this example embodiment to select an actualization policy is described with reference to FIG. 13. FIG. 13 is a flowchart showing the operation of the actualization policy selection process by the second actualization policy judgment unit 107 of the second example embodiment.

Each processing of step S2510 to step S2520 is similar to each processing of step S1510 to step S1520 respectively shown in FIG. 9.

After receiving the similarity score, the second actualization policy judgment unit 107 inputs all the abstract configurations included in the input to the priority score computation unit 108. The priority score computation unit 108 computes a priority score for each abstract configuration, respectively (step S2530).

Next, the priority score computation unit 108 returns each computed priority score to the second actualization policy judgment unit 107. Next, the second actualization policy judgment unit 107 computes the integration score, in which the similarity score and the priority score are integrated, for each abstract configuration (step S2540).

Each processing of step S2550 to step S2600 is similar to each processing of step S1530 to step S1580 respectively, where the similarity score is replaced by the integration score shown in FIG. 9.

The actualization configuration derivation process, the hint information assignment process, and the similarity score computation process by the system configuration derivation device 110 of this example embodiment are the same as the actualization configuration derivation process shown in FIG. 6, the hint information assignment process shown in FIG. 10, and the similarity score computation process shown in FIG. 11, respectively.

[Description of Effect]

The second actualization policy judgment unit 107 of this example embodiment refers to the similarity score computed by the external design information reflection unit 103 on the basis of the hint information assigned to the abstract configuration, as well as another type of score computed for the abstract configuration. The second actualization policy judgment unit 107 uses the two types of scores to select the abstract configuration that is considered to be actualized next.

The second actualization policy judgment unit 107 of this example embodiment also considers the priority score computed by the priority score computation unit 108 in addition to the similarity score. Therefore, the system configuration derivation device 110 of this example embodiment can reflect the priority given by the priority score computation unit 108 in the actualization configuration, in addition to the property of being similar to the design results of the external design device.

### Example Embodiment 3

[Description of Configuration]

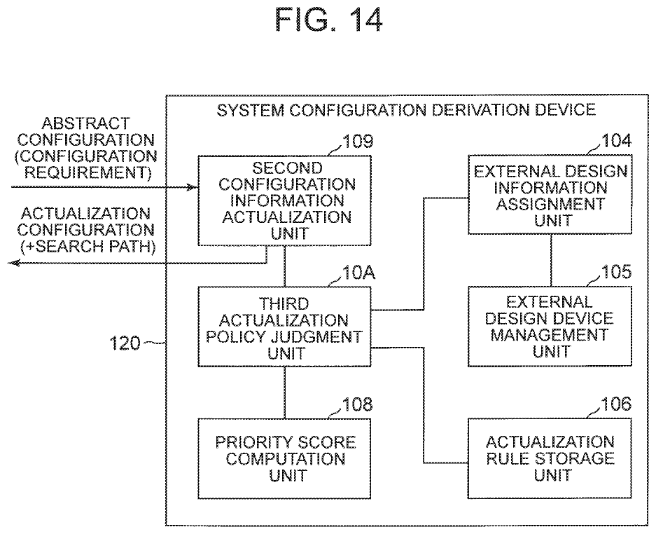

Next, the system configuration derivation device in the third example embodiment of the present invention is described with reference to the drawings. FIG. 14 is a block diagram showing a configuration example of the system configuration derivation device of the third example embodiment according to the present invention.

The system configuration derivation device 120 of this example embodiment differs from the system configuration derivation device 100 shown in FIG. 1 in that the configuration information actualization unit 101 is replaced by the second configuration information actualization unit 109 and the actualization policy judgment unit 102 is replaced by the third actualization policy judgment unit 10A, respectively.

The system configuration derivation device 120 of this example embodiment differs from the system configuration derivation device 100 shown in FIG. 1 in that it does not have the external design information reflection unit 103. Also, the system configuration derivation device 120 has the priority score computation unit 108 of the second example embodiment.

Similar to the system configuration derivation device 100 shown in FIG. 1, the system configuration derivation device 120 of this example embodiment has an external design information assignment unit 104, an external design device management unit 105, and an actualization rule storage unit 106. As shown in FIG. 14, the external design information assignment unit 104 and the priority score computation unit 108 are connected to the third actualization policy judgment unit 10A, respectively.

[Description of Operation]

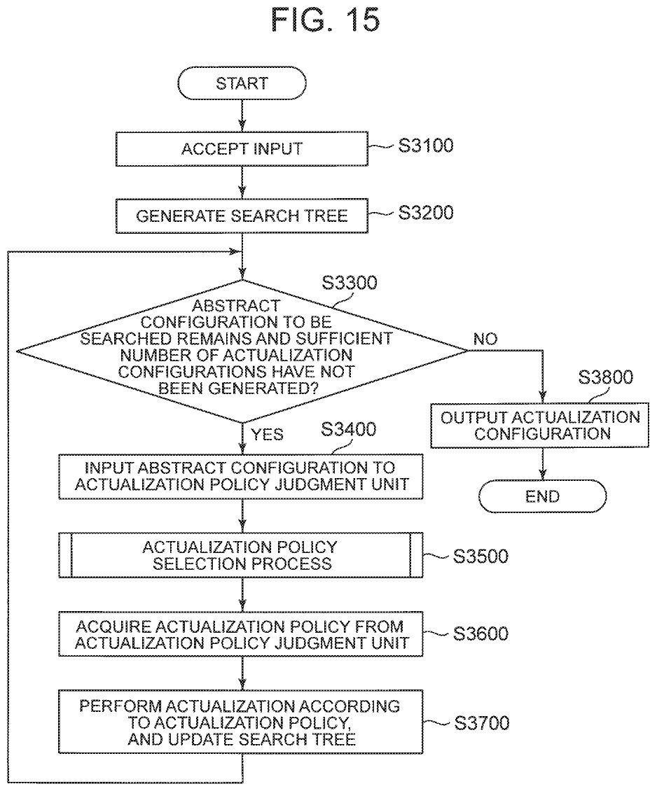

Hereinafter, the operation of the system configuration derivation device 120 of this example embodiment to design an ICT system is described with reference to FIG. 15. FIG. 15 is a flowchart showing the operation of the actualization configuration derivation process by the system configuration derivation device 120 of the third example embodiment.

Each processing of step S3100 to step S3700 is similar to each processing of step S1100 to step S1700 respectively shown in FIG. 6. The processing of step S3800 is similar to the processing of step S2000 shown in FIG. 6.

In other words, in the actualization configuration derivation process of this example embodiment, unlike the actualization configuration derivation process of the first example embodiment, the hint information assignment process is not executed.

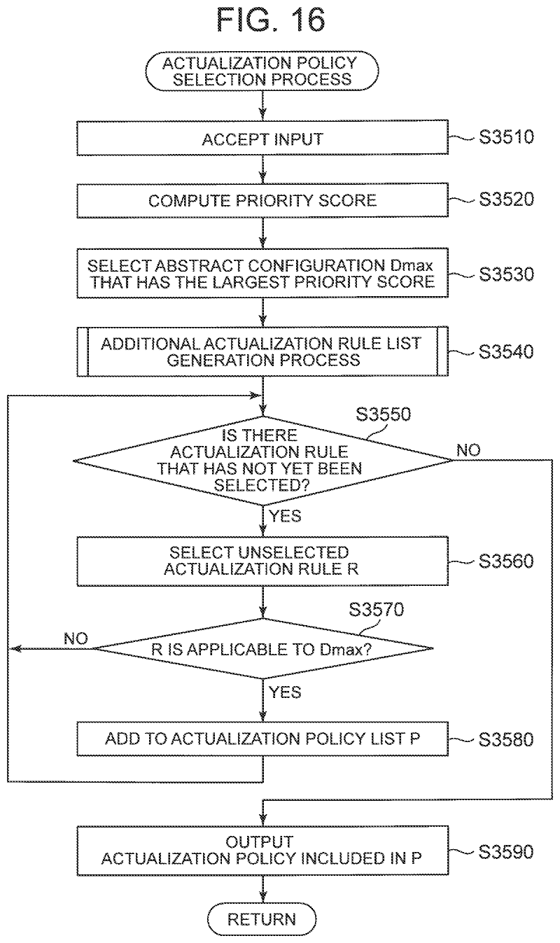

Next, the operation of the third actualization policy judgment unit 10A of this example embodiment to select an actualization policy is described with reference to FIG. 16. FIG. 16 is a flowchart showing the operation of the actualization policy selection process by the third actualization policy judgment unit 10A of the third example embodiment.

First, the third actualization policy judgment unit 10A receives a set of abstract configurations as input from the second configuration information actualization unit 109 (step S3510).

Next, the third actualization policy judgment unit 10A inputs all the abstract configurations included in the input to the priority score computation unit 108. The priority score computation unit 108, which has been inputted with the abstract configurations, computes a priority score for each abstract configuration, respectively (step S3520).

Next, the third actualization policy judgment unit 10A receives the priority score computed in step S3520 from the priority score computation unit 108. The third actualization policy judgment unit 10A selects one abstract configuration Dmax that takes the largest priority score among the received priority scores (step S3530).

Next, the third actualization policy judgment unit 10A executes the additional actualization rule list generation process (step S3540). The additional actualization rule list generation process is a process which generates an additional actualization rule list that directly reflect the output results of the external design information assignment unit 104 in addition to the set of actualization rules managed in the actualization rule storage unit 106 as candidates for the actualization rules R.

After the additional actualization rule list generation process is executed, the third actualization policy judgment unit 10A retrieves the set of actualization rules managed in the actualization rule storage unit 106 and the set of additional actualization rules generated in step S3540.

Each processing of step S3550 to step S3590 is similar to each processing of step S2560 to step S2600 respectively shown in FIG. 13.

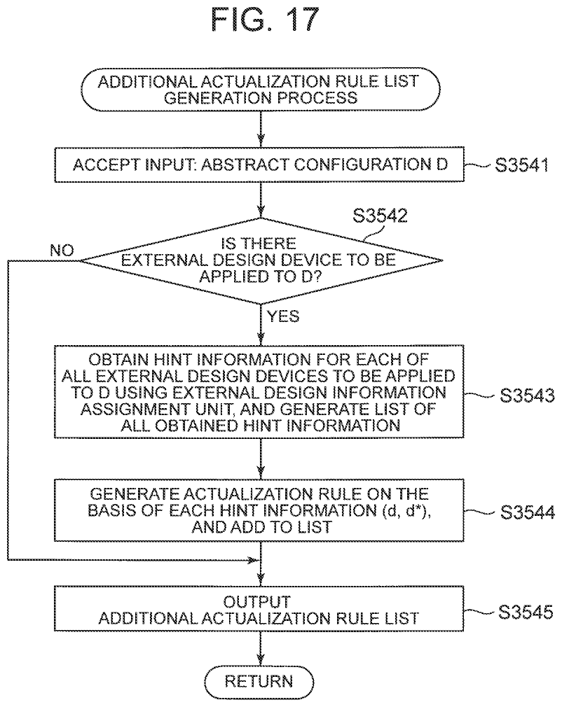

Next, the operation of the third actualization policy judgment unit 10A of this example embodiment to generate a list of actualization rules to be added to the candidates of actualization rule R as additional actualization rules is described with reference to FIG. 17.

FIG. 17 is a flowchart showing the operation of the additional actualization rule list generation process by the third actualization policy judgment unit 10A of the third example embodiment. The additional actualization rule list generation process shown in FIG. 17 is the processing of step S3540 shown in FIG. 16.

First, the third actualization policy judgment unit 10A takes the abstract configuration D as input (step S3541). The abstract configuration D to be input is the abstract configuration Dmax selected in step S3530.

Next, the third actualization policy judgment unit 10A confirms whether or not there is an external design device to be applied to the input abstract configuration D (step S3542). The third actualization policy judgment unit 10A may, for example, use the criteria used by the configuration information actualization unit 101 in step S1800 as the criteria for determining whether or not there is an external design device applicable to the abstract configuration D.

If it is determined that it is not desirable to apply an external design device (No in step S3542), the third actualization policy judgment unit 10A outputs an empty list as an additional actualization rule list (step S3545). After outputting the additional actualization rule list, the third actualization policy judgment unit 10A returns to the actualization policy selection process.

If it is determined that there is an external design device to be applied to the abstract configuration D (Yes in step S3542), the third actualization policy judgment unit 10A calls the external design information assignment unit 104 to obtain the hint information (d, d*) for each of all external design devices to be applied. Next, the third actualization policy judgment unit 10A generates a list of all obtained hint information (step S3543).

Next, the third actualization policy judgment unit 10A generates actualization rules on the basis of each hint information (d, d*) generated in step S3543, with d as the left side and d* as the right side, respectively, such that there are no additional constraints (step S3544).

Next, the third actualization policy judgment unit 10A outputs the generated list of actualization rules as an additional actualization rule list (step S3545). After outputting the additional actualization rule list, the third actualization policy judgment unit 10A returns to the actualization policy selection process.

[Description of Effect]

The system configuration derivation device 120 of this example embodiment can add an abstract configuration that directly reflects the output results of the external design device obtained through the external design information assignment unit 104 as a candidate for the search process for an actualization configuration by the second configuration information actualization unit 109.

Therefore, the system configuration derivation device 120 of this example embodiment can derive a system configuration that more directly reflects the design results of the external design device.

### Example Embodiment 4

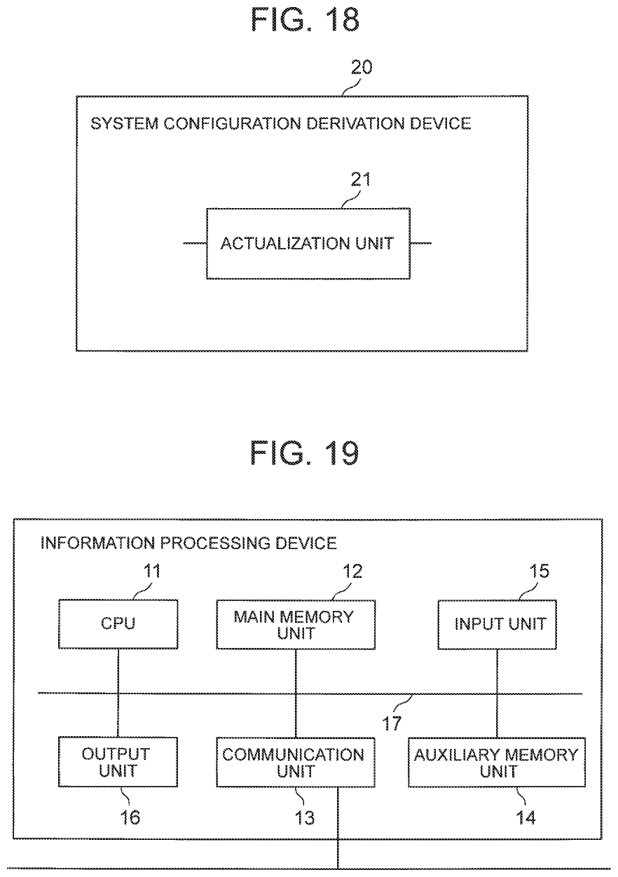

Next, the system configuration derivation device of the fourth example embodiment according to the present invention is described with reference to the drawings. FIG. 18 is a block diagram showing a configuration example of the system configuration derivation device of the fourth example embodiment according to the present invention.

The system configuration derivation device 20 shown in FIG. 18 includes an actualization unit 21 (for example, the configuration information actualization unit 101) which actualizes abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

With such a configuration, the system configuration derivation device can derive a system configuration that reflects the design tendency of an external design device that restricts the problem to be handled.

Also, the actualization unit 21 may actualize the abstract configuration information by repeatedly executing operations to confirm a part of the unconfirmed portion included in the abstract configuration information using the actualization rule.

With such a configuration, the system configuration derivation device can actualize the abstract configuration information using a search tree.

Also, the system configuration derivation device 20 may include a generation unit (for example, the actualization policy judgment unit 102) which generates operation information which is information about the next operation to be executed, and includes the part of the unconfirmed portion of the confirmed target and the actualization rule to be used, wherein the actualization unit 21 may execute operation according to the generated operation information.

With such a configuration, the system configuration derivation device can actualize the abstract configuration information more efficiently.

Also, the system configuration derivation device 20 may include a computation unit (for example, the external design information reflection unit 103) which computes a similarity score indicating the similarity between the result of actualizing by the external design device of the part of the unconfirmed portion and the part of the unconfirmed portion using the actualization information, wherein the generation unit may generate the operation information using the computed similarity score.

With such a configuration, the system configuration derivation device can actualize the abstract configuration information so that it is closer to the design of the external design device.

Also, the generation unit may generate the operation information using the score computed from the abstract configuration information according to the predetermined criteria.

With such a configuration, the system configuration derivation device can actualize the abstract configuration information using scores other than the similarity score.

Also, the actualization unit 21 may generate the actualization rule on the basis of the actualization information.

With such a configuration, the system configuration derivation device can derive a system configuration that more directly reflects the design results of the external design device.

Also, the system configuration derivation device 20 may include an assignment unit (for example, the external design information assignment unit 104) which assigns the actualization information to the abstract configuration information.

With such a configuration, the system configuration derivation device can independently derive a system configuration that reflects the design tendency of the external design device.

Also, the actualization unit 21 may output actualization configuration information which is information that indicates the configuration of the system without the unconfirmed portion as a result of actualization.

With such a configuration, the system configuration derivation device can derive system configuration information that does not include any unconfirmed portion.

Also, the system configuration derivation device 20 may include a management unit (for example, the external design device management unit 105) which manages the external design device by associating it with a converter, etc. to be applied to some of the abstract configuration information.

With such a configuration, the system configuration derivation device can easily perform the input and output of abstract configuration information to the external design device.

Also, the system configuration derivation device 20 may include a storage unit (for example, the actualization rule storage unit 106) which stores the actualization rule.

Hereinafter, specific examples of the hardware configuration of the system configuration derivation device of each example embodiment are described. FIG. 19 is an explanatory diagram showing an example of the hardware configuration of an information processing device capable of realizing the system configuration derivation device of each example embodiment according to the present invention.

The information processing device (computer) shown in FIG. 19 has a CPU (Central Processing Unit) 11, a main memory unit 12, a communication unit 13, and an auxiliary memory unit 14. It also has an input unit 15 for user operation and an output unit 16 for presenting the processing results or the progress of the processing to the user.

The information processing device is realized by software, with the CPU 11 shown in FIG. 19 executing a program that provides the functions that each component has.

In other words, each function is realized by software as the CPU 11 loads the program stored in the auxiliary memory unit 14 into the main memory unit 12 and executes it to control the operation of the information processing device.

The information processing device shown in FIG. 19 may have a DSP (Digital Signal Processor) instead of the CPU 11. Alternatively, the information processing device shown in FIG. 19 may have both the CPU 11 and the DSP.

The main memory unit 12 is used as a working area for data and a temporary storage area for data. The main memory unit 12 is, for example, RAM (Random Access Memory).

The communication unit 13 has the function of inputting and outputting data to and from peripheral devices via a wired network or a wireless network (information and communication network).

The auxiliary memory 14 is a non-temporary tangible storage medium. For example, a magnetic disk, a magneto-optical disk, a CD-ROM (Compact Disk Read Only Memory), a DVD-ROM (Digital Versatile Disk Read Only Memory), and a semiconductor memory are examples of non-temporary tangible storage media.

The input unit 15 has the function of inputting data and processing instructions. The input unit 15 is, for example, an input device such as a keyboard or mouse.

The output unit 16 has the function of outputting data. The output unit 16 is, for example, a display device such as a liquid crystal display device, or a printing device such as a printer.

As shown in FIG. 19, in the information processing device, each component is connected to the system bus 17.

The auxiliary memory unit 14 stores programs for realizing, for example, the configuration information actualization unit 101, the actualization policy judgment unit 102, the external design information reflection unit 103, the external design information assignment unit 104, and the external design device management unit 105 in the first example embodiment.

The auxiliary memory unit 14 stores programs for realizing, for example, the configuration information actualization unit 101, the external design information reflection unit 103, the external design information assignment unit 104, the external design device management unit 105, the second actualization policy judgment unit 107, and the priority score computation unit 108 in the second example embodiment.

The auxiliary memory unit 14 stores programs for realizing, for example, the external design information assignment unit 104, the external design device management unit 105, the priority score computation unit 108, the second configuration information actualization unit 109, and the third actualization policy judgment unit 10A in the third example embodiment.

The auxiliary memory unit 14 stores, for example, a program for realizing the actualization unit 21 in the fourth example embodiment. The actualization rule storage unit 106 is realized, for example, by the main memory unit 12.

The system configuration derivation device may be realized by hardware. For example, the system configuration derivation device 100 may be implemented with a circuit that includes hardware components such as LSI (Large Scale Integration) that realize the functions shown in FIG. 1.

Some or all of the components may be realized by general-purpose circuits (circuitry) or dedicated circuits, processors, etc., or combinations of these. They may be configured by a single chip (for example, the LSI described above) or by multiple chips connected via a bus. Some or all of each component may be realized by a combination of the above-mentioned circuits, etc. and programs.

When some or all of each component is realized by multiple information processing devices, circuits, etc., the multiple information processing devices, circuits, etc. may be centrally located or distributed. For example, the information processing devices, circuits, etc. may be implemented as a client-and-server system, cloud computing system, etc., each of which is connected via a communication network.

While the present invention has been explained with reference to the example embodiments and examples, the present invention is not limited to the aforementioned example embodiments and examples. Various changes understandable to those skilled in the art within the scope of the present invention can be made to the structures and details of the present invention.

This application claims priority based on Japanese patent application 2019-037180 filed on Mar. 1, 2019, the entire disclosure of which is hereby incorporated herein.

Some or all of the aforementioned example embodiment can be described as supplementary notes mentioned below, but are not limited to the following supplementary notes.

(Supplementary note 1) A system configuration derivation device comprising: an actualization unit which actualizes abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

(Supplementary note 2) The system configuration derivation device according to Supplementary note 1, wherein the actualization unit actualizes the abstract configuration information by repeatedly executing operations to confirm a part of the unconfirmed portion included in the abstract configuration information using the actualization rule.

(Supplementary note 3) The system configuration derivation device according to Supplementary note 2, further comprising: a generation unit which generates operation information which is information about the next operation to be executed, and includes the part of the unconfirmed portion of the confirmed target and the actualization rule to be used, wherein the actualization unit executes operation according to the generated operation information.

(Supplementary note 4) The system configuration derivation device according to Supplementary note 3, further comprising: a computation unit which computes a similarity score indicating the similarity between the result of actualizing by the external design device of the part of the unconfirmed portion and the part of the unconfirmed portion using the actualization information, wherein the generation unit generates the operation information using the computed similarity score.

(Supplementary note 5) The system configuration derivation device according to Supplementary note 3 or 4, wherein the generation unit generates the operation information using the score computed from the abstract configuration information according to the predetermined criteria.

(Supplementary note 6) The system configuration derivation device according to any one of Supplementary notes 1 to 5, wherein the actualization unit generates the actualization rule on the basis of the actualization information.

(Supplementary note 7) The system configuration derivation device according to any one of Supplementary notes 1 to 6, further comprising: an assignment unit which assigns the actualization information to the abstract configuration information.

(Supplementary note 8) The system configuration derivation device according to any one of Supplementary notes 1 to 7, wherein the actualization unit outputs actualization configuration information which is information that indicates the configuration of the system without the unconfirmed portion as a result of actualization.

(Supplementary note 9) The system configuration derivation device according to any one of Supplementary notes 1 to 8, further comprising: a management unit which manages the external design device by associating it with a converter to be applied to some of the abstract configuration information.

(Supplementary note 10) The system configuration derivation device according to any one of Supplementary notes 1 to 9, further comprising: a storage unit which stores the actualization rule.

(Supplementary note 11) A system configuration derivation method comprising: actualizing abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

(Supplementary note 12) A non-transitory computer-readable capturing medium having captured therein a system configuration derivation program for causing a computer to execute: actualizing abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

### REFERENCE SIGNS LIST

11 CPU
12 Main memory unit
13 Communication unit
14 Auxiliary memory unit
15 Input unit
16 Output unit
17 System bus
20, 100, 110, 120 System configuration derivation device
21 Actualization unit
101 Configuration information actualization unit
102 Actualization policy judgment unit
103 External design information reflection unit
104 External design information assignment unit
105 External design device management unit
106 Actualization rule storage unit
107 Second actualization policy judgment unit
108 Priority score computation unit
109 Second configuration information actualization unit
10A Third actualization policy judgment unit

1. A system configuration derivation device comprising:
at least one processor; and
a memory coupled to the at least one processor;
wherein the at least one processor is configured to one or more instruction to:
actualize abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

2. The system configuration derivation device according to claim 1, wherein the at least one processor is configured to one or more instruction to:
actualize the abstract configuration information by repeatedly executing operations to confirm a part of the unconfirmed portion included in the abstract configuration information using the actualization rule.

3. The system configuration derivation device according to claim 2, wherein the at least one processor is further configured to one or more instruction to:
generate operation information which is information about the next operation to be executed, and includes the part of the unconfirmed portion of the confirmed target and the actualization rule to be used, and
execute operation according to the generated operation information.

4. The system configuration derivation device according to claim 3, wherein the at least one processor is further configured to one or more instruction to:
compute a similarity score indicating the similarity between the result of actualizing by the external design device of the part of the unconfirmed portion and the part of the unconfirmed portion using the actualization information, and
generate the operation information using the computed similarity score.

5. The system configuration derivation device according to claim 3, wherein the at least one processor is configured to one or more instruction to:
generate the operation information using the score computed from the abstract configuration information according to the predetermined criteria.

6. The system configuration derivation device according to claim 1, wherein the at least one processor is configured to one or more instruction to:
generate the actualization rule on the basis of the actualization information.

7. The system configuration derivation device according to claim 1, wherein the at least one processor is further configured to one or more instruction to:
assign the actualization information to the abstract configuration information.

8. The system configuration derivation device according to claim 1, wherein the at least one processor is configured to one or more instruction to:
output actualization configuration information which is information that indicates the configuration of the system without the unconfirmed portion as a result of actualization.

9. The system configuration derivation device according to claim 1, wherein the at least one processor is further configured to one or more instruction to:
manage the external design device by associating it with a converter to be applied to some of the abstract configuration information.

10. The system configuration derivation device according to claim 1, wherein the at least one processor is further configured to one or more instruction to:
store the actualization rule.

11. A system configuration derivation method comprising:
actualizing abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

12. A non-transitory computer-readable capturing medium having captured therein a system configuration derivation program for causing a computer to execute:
actualizing abstract configuration information including an unconfirmed portion and indicating a system configuration, the actualization being performed on the basis of an actualization rule in which a method for actualizing the abstract configuration information by confirming the unconfirmed portion of the abstract configuration information is defined, and actualization information which indicates the results of actualizing the unconfirmed portion by using an external design device that can actualize the abstract configuration information only for a predetermined problem.

13. The system configuration derivation device according to claim 4, wherein the at least one processor is configured to one or more instruction to:
generate the operation information using the score computed from the abstract configuration information according to the predetermined criteria.

14. The system configuration derivation device according to claim 2, wherein the at least one processor is configured to one or more instruction to:
generate the actualization rule on the basis of the actualization information.

15. The system configuration derivation device according to claim 3, wherein the at least one processor is configured to one or more instruction to:
generate the actualization rule on the basis of the actualization information.

16. The system configuration derivation device according to claim 4, wherein the at least one processor is configured to one or more instruction to:
generate the actualization rule on the basis of the actualization information.

17. The system configuration derivation device according to claim 5, wherein the at least one processor is configured to one or more instruction to:
generate the actualization rule on the basis of the actualization information.

18. The system configuration derivation device according to claim 13, wherein the at least one processor is configured to one or more instruction to:
generate the actualization rule on the basis of the actualization information.

19. The system configuration derivation device according to claim 2, wherein the at least one processor is further configured to one or more instruction to:
assign the actualization information to the abstract configuration information.

20. The system configuration derivation device according to claim 3, wherein the at least one processor is further configured to one or more instruction to:
assign the actualization information to the abstract configuration information.
